(19) United States
(12) Patent Application Publication
(10) Pub. No.: US 2025/0089203 A1
(43) Pub. Date: Mar. 13, 2025

(54) FLUIDIC OSCILLATORS FOR THE PASSIVE COOLING OF ELECTRONIC DEVICES

(71) Applicant: Toyota Motor Engineering & Manufacturing North America, Inc., Plano, TX (US)

(72) Inventors: Shailesh JOSHI, Ann Arbor, MI (US); Ercan DEDE, Ann Arbor, MI (US)

(73) Assignee: Toyota Motor Engineering & Manufacturing North America, Inc., Plano, TX (US)

(21) Appl. No.: 18/466,345

(22) Filed: Sep. 13, 2023

(51) Int. Cl. H05K 7/20; B64D 33/08

(52) U.S. Cl. CPC H05K 7/20172; B64D 33/08; H05K 7/20863; B64U 10/20; B64U 2201/10

(57) ABSTRACT

Impingement cooling systems, electronic motor assemblies, and Electric vertical take-off and landing (eVTOL) systems are disclosed. In one embodiment, an impingement cooling system includes an electronic device casing downstream a propulsion air-flow and one or more electronic devices housed in the electronic device casing. A plurality of fins extend from the electronic device casing and one or more fluidic oscillators are coupled to the electronic device casing, wherein the fluidic oscillators receive the propulsion air-flow and provide an oscillatory air-flow over the electronic device casing and the plurality of fins.

### TECHNICAL FIELD

The embodiments described herein generally relate to a passive cooling system, in particular, to a fluidic oscillator cooling system in which propulsion air-flow is utilized by fluidic oscillators that provide an oscillatory air-flow to cool various electronic devices.

### BACKGROUND

Electric vertical take-off and landing (eVTOL) aircrafts may take off from a source location, e.g., with a load in the form of purchased goods, for delivery to a location, travel a certain distance in the air, drop off the load, and return to the source location. Operation of eVTOL aircrafts, however, suffer from deficiencies. For example, during take-off and landing operations, electronics included within the eVTOL aircrafts may experience sudden increases in operating temperatures due to increased power demands, which adversely impact the operational life of these devices, and by extension, the operational life of eVTOL aircrafts.

Accordingly, a need exists for alternative cooling systems to cool motors and various electronic devices of eVTOL aircrafts.

### SUMMARY

In one embodiment, an impingement cooling system is provided. The impingement cooling system includes an electronic device casing downstream a propulsion air-flow. The electronic device casing houses one or more electronic devices and a plurality of fins extends from the electronic device casing. The system further includes one or more fluidic oscillators coupled to the electronic device casing. The one or more fluidic oscillators receive the propulsion air-flow and provide an oscillatory air-flow over the electronic casing and the plurality of fins.

In another embodiment, an electric motor assembly includes a motor housing having an end face and a motor within the motor housing. The electric motor assembly also includes a propulsion component coupled to the motor that generates a propulsion air-flow downstream the propulsion component. An electronics assembly is disposed on the end face of the motor housing. The electronics assembly includes an electronic device casing downstream the propulsion air-flow, configured to house one or more electronic devices. A plurality of fins extends from the electronic device casing. The electronics assembly also includes one or more fluidic oscillators coupled to the electronic device casing. The one or more fluidic oscillators receive the propulsion air-flow and provide an oscillatory air-flow over the electronic device casing and the plurality of fins.

In yet another embodiment, an eVTOL system includes a motor housing having an end face. A motor is within the motor housing. At least one propeller is mechanically coupled to the motor. The propeller generates a propulsion air-flow downstream the propeller. An electronics assembly is disposed on the end face of the motor housing. The electronics assembly is downstream the propulsion air-flow and includes an electronic device casing configured to house one or more electronic devices. The electronic device casing includes a plurality of fins extending from the electronic device casing. There are also one or more fluidic oscillators coupled to the electronic device casing. The one or more fluidic oscillators receive the propulsion air-flow and provide an oscillatory air-flow over the electronic device casing and the plurality of fins.

These and additional features provided by the embodiments described herein will be more fully understood in view of the following detailed description, in conjunction with the drawings.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1A schematically illustrates a top view of an impingement cooling system included as part of an electronic device casing, wherein a fluidic oscillator is positioned between two fins of the electronic device casing, according to one or more embodiments described and illustrated herein;

FIG. 1B schematically illustrates a side-view of an electronic device casing with a propulsion air-flow going over the electronic device casing, according to one or more embodiments described and illustrated herein;

FIG. 2 schematically illustrates the fluidic oscillator positioned between two fins of the electronic device casing, wherein the fluidic oscillator is integrated into an electronic device casing and acts as a fin, according to one or more embodiments described and illustrated herein;

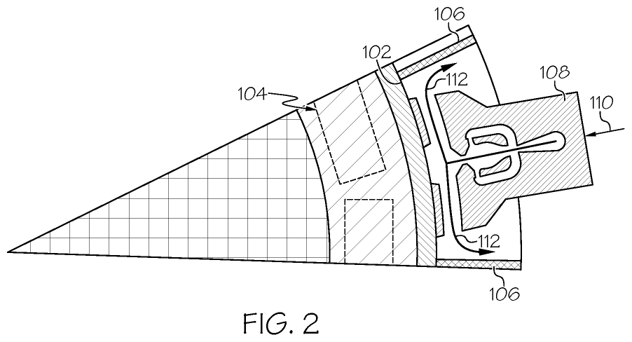

FIG. 3 schematically illustrates a cross-sectional area of a feedback-free fluidic oscillator, according to one or more embodiments described and illustrated herein;

FIG. 4 schematically illustrates a cross-sectional area of a double-feedback fluidic oscillator, according to one or more embodiments described and illustrated herein;

FIG. 5 schematically illustrates a side-view of an electric motor assembly, according to one or more embodiments described and illustrated herein; and

FIG. 6 schematically illustrates an eVTOL aircraft, according to one or more embodiments described and illustrated herein.

### DETAILED DESCRIPTION

Embodiments described herein relate to systems capable of cooling electronic devices. In embodiments, an impingement cooling system includes an electronic device casing configured to house one or more electronic devices, a plurality of fins extending from the electronic device casing, and one or more fluidic oscillators coupled to the electronic device casing. The one or more fluidic oscillators receive a propulsion air-flow and provide oscillatory air-flow over the electronic device casing and the plurality of fins. This results in enhanced cooling of the electronic devices.

Electric vertical take-off and landing (eVTOL) aircrafts may provide a way of delivering people and goods to various locations in a cost and energy efficient manner. However, as stated above, eVTOL aircrafts suffer from cooling deficiencies. During specific operation conditions such as, e.g., take-off, landing, and hovering, operating temperatures of the electronic devices within eVTOL aircrafts may exceed threshold operational temperatures, namely threshold operational temperatures that are considered suitable for ensuring long operational life for these electronic devices.

Embodiments described herein are generally directed to impingement cooling systems integrated into an electronic device casing. By utilizing propulsion air-flow, the impingement cooling system provides oscillatory air-flow over the electronic device casing and the plurality of fins on the electronic device casing. The oscillatory air-flow over the electronic device casing and the plurality of fins improves heat transfer between the electronic device casing and the surrounding environment. This allows the eVTOL aircraft to operate without exceeding threshold operational temperatures.

Embodiments described herein also include an electric motor assembly that includes a motor within a motor housing. The motor provides energy to a propulsion component. An electronics assembly includes the electronic device casing and the fluidic oscillators. The fluidic oscillators provide the oscillatory flow over the electronic device casing and the plurality of fins.

The embodiments disclosed herein also describe an eVTOL system that utilizes propulsion air-flow to cool electronic devices of the eVTOL system through the use of fluidic oscillators coupled to the electronic device casing. The eVTOL system utilizes its own propulsion air-flow, which is provided by at least one propeller, to cool a motor and electronic devices of the eVTOL system through the use of the fluidic oscillators. The oscillatory air-flow over the electronic device casing and the plurality of fins improves heat transfer between the electronic device casing and the surrounding environment. This allows the eVTOL aircraft to function without exceeding threshold operational temperatures.

As used herein, the following terms are generally defined in the manner below. The term “longitudinal” means a direction that is in line with the propulsion air-flow direction. The term “lateral” means a direction that is approximately 90 degrees from the propulsion air-flow direction.

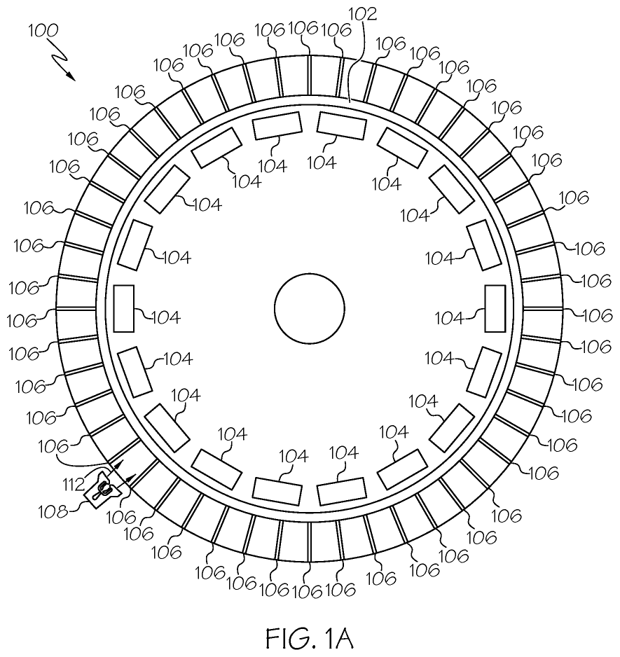

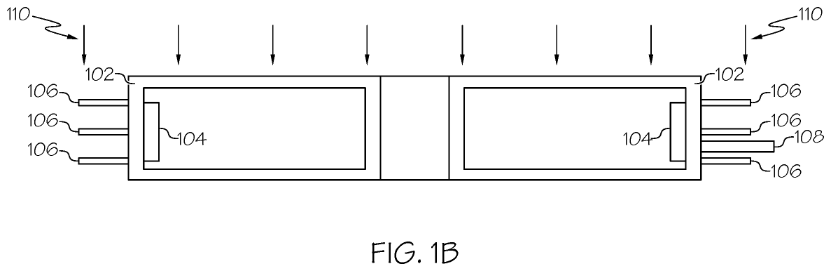

Referring now to the drawings, FIG. 1A schematically depicts a top-view of an impingement cooling system 100 included as part of an electronic device casing 102. One or more electronic devices 104 are housed within the electronic device casing 102. A plurality of fins 106 extends from the electronic device casing 102. One or more fluidic oscillators 108 are coupled to the electronic device casing 102. The electronic device casing 102 is downstream a propulsion air-flow 110. The one or more fluidic oscillators 108 receive the propulsion air-flow 110 and provide an oscillatory air-flow 112 over the electronic device casing 102 and the plurality of fins 106.

FIG. 1B depicts a side-view of the impingement cooling system 100. The electronic devices 104 are housed within the electronic device casing 102. The electronic device casing 102 is downstream the propulsion air-flow 110. In other embodiments, the electronic device casing 102 may be upstream the propulsion air-flow 110. The electronic devices 104 may include a motor, inverter circuits, power modules, a plurality of power modules, controllers, capacitors, or any other suitable electronic device. The plurality of power modules may include power electronic devices, such as an insulated gate bipolar transistor that converts direct current (DC) power from a battery to alternating current (AC) power. The electronic devices 104 may be arranged so that the plurality of power modules are arranged around a circumference of the motor, around an inside wall of the electronic device casing 102, or in any suitable manner within the electronic device casing 102. The electronic device casing 102 may be circular, rectangular, or any shape suitable to house the electronic devices 104. The electronic devices 104 generate heat that is then transferred to the electronic device casing 102 and the plurality of fins 106 and expelled into the atmosphere. The electronic device casing 102 may be made up of a thermally conductive material, such as aluminum or copper.

The plurality of fins 106 extend from the electronic device casing 102. The plurality of fins 106 may be coupled to the electronic device casing 102 through bolts, screws, adhesive, or any other suitable coupling means. The plurality of fins 106 may also be integrated into and cast as part of the electronic device casing 102. The plurality of fins 106 may extend from the electronic device casing 102 in varying frequencies. There may be any number of the plurality of fins 106 extending from the electronic device casing 102. The plurality of fins 106 may be spaced out evenly or in varying frequencies. The plurality of fins 106 may also be layered above or beneath one another longitudinally.

The plurality of fins 106 are configured to improve cooling of the electronic device casing 102 and, thus, improve cooling of the electronic devices 104. The electronic devices 104 generate heat to the electronic device casing 102. The plurality of fins 106 provide an increased surface area for heat to dissipate from the electronic device casing 102. The plurality of fins 106 may be longitudinal fins, lateral fins, or curved fins.

Referring again to FIG. 1A, the one or more fluidic oscillators 108 provide the oscillatory air-flow 112 over the electronic device casing 102. The one or more fluidic oscillators 108 may be coupled to the electronic device casing 102 by way of fasteners (e.g., bolts and nuts). The one or more fluidic oscillators 108 may also be integrated into and cast as part of the electronic device casing 102. The one or more fluidic oscillators 108 may be made from ceramic, plastic, metal, or any other suitable material. The fluidic oscillators 108 may also be 3D-printed from thermoplastics or metals.

The fluidic oscillators 108 may be oriented anywhere on the electronic device casing 102. In some embodiments, the fluidic oscillators 108 are coupled between each set of the plurality of fins 106. The fluidic oscillators 108 may also be coupled over each of the plurality of fins 106 so that the oscillatory air-flow 112 oscillates from one side of each of the plurality of fins 106 to another side of each of the plurality of fins 106.

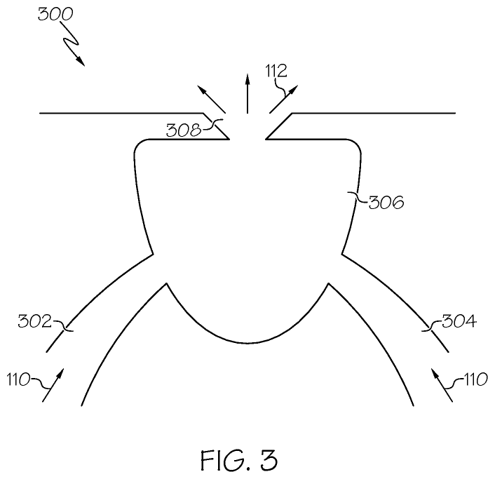

The fluidic oscillators 108 may be configured to disperse the oscillatory air-flow 112 over the electronic device casing 102 or the plurality of fins 106. The fluidic oscillators 108 may disperse the oscillatory air-flow 112 longitudinally, laterally, or a combination thereof (such as in diagonal or circular flow). In other embodiments, as depicted in FIG. 3, the fluidic oscillators 108 may act as fins of the electronic device casing 102. The fluidic oscillators 108 may be coupled to the electronic device casing 102 so that the fluidic oscillators 108 act as one of the plurality of fins 106 (i.e. heat from the electronic devices 104 and the electronic device casing 102 is dissipated by the fluidic oscillators 108). The fluidic oscillators 108 in the present disclosure may produce the oscillatory air-flow 112 over positions of the plurality of fins 106 and/or the electronic device casing 102 through the use of moving parts or without moving parts. The fluidic oscillators 108 may be feedback-free oscillators, double-feedback channel fluidic oscillators, or any other suitable fluidic oscillator configuration.

FIG. 3 depicts a cross-sectional area of a feedback-free fluidic oscillator 300. The feedback-free fluidic oscillator 300 includes a first supply channel 302, a second supply channel 304, a feed-back free mixing chamber 306, and a feedback-free outlet channel 308. The first supply channel 302 and the second supply channel 304 receive the propulsion air-flow 110 and provide it to the feedback-free mixing chamber 306. The feedback-free mixing chamber 306 is shaped in such a way that it provides the oscillatory air-flow 112 out of the feedback-free outlet channel 308 when the first supply channel 302 and second supply channel 304 provide the propulsion air-flow 110 to the feedback-free mixing chamber 306. The propulsion air-flow 110 from the first supply channel 302 and the second supply channel 304 collide at an angle in the feedback-free mixing chamber 306. This results in a shear layer, causing the propulsion air-flow 110 supplied by the first supply channel 302 and second supply channel 304 to come out of the feedback-free outlet channel 308 as the oscillatory air-flow 112.

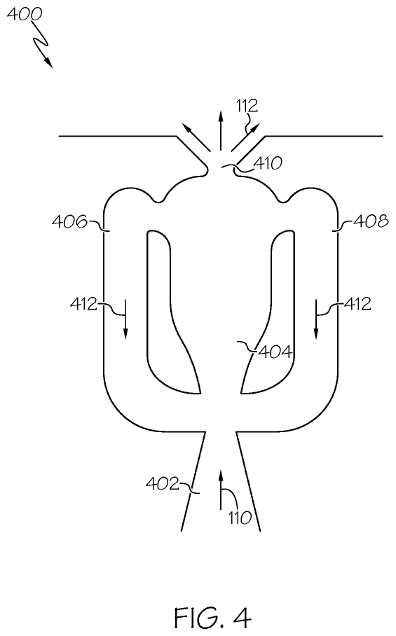

FIG. 4 depicts a cross-sectional area of a double-feedback fluidic oscillator 400. The double-feedback fluidic oscillator 400 includes a double-feedback supply channel 402, a double-feedback mixing chamber 404, a first feedback channel 406, a second feedback channel 408, and a double-feedback outlet channel 410. The double-feedback supply channel 402 receives the propulsion air-flow 110 and provides the propulsion air-flow 110 to the double-feedback mixing chamber 404. The first feedback channel 406 and the second feedback channel 408 provide a recycled air 412 to the double-feedback supply channel 402. This causes propulsion air-flow 110 being provided into the double-feedback mixing chamber 404 from the double-feedback supply channel 402 to flip from one side of the double-feedback mixing chamber 404 to the other. This causes the oscillatory air-flow 112 to come out of the double-feedback outlet channel 410 when the double-feedback supply channel 402 provides the propulsion air-flow 110 to the double-feedback mixing chamber 404.

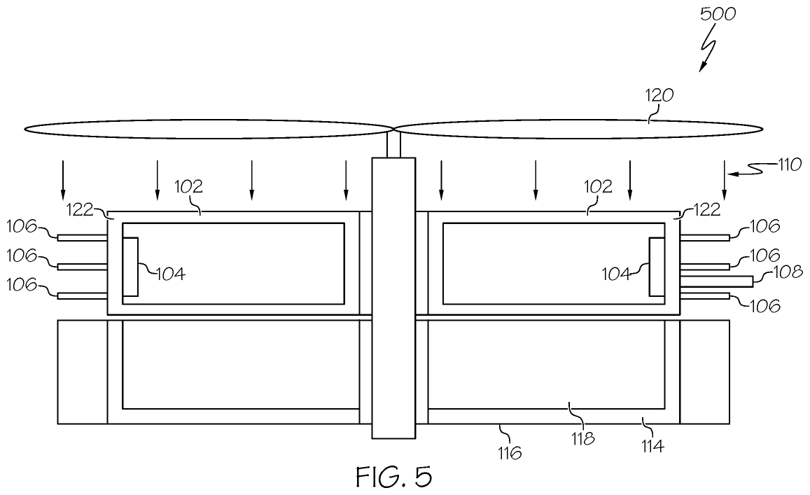

In some embodiments, an electric motor assembly 500 is disclosed, as depicted in FIG. 5. The electric motor assembly 500 includes a motor housing 114. The motor housing 114 has an end face 116. A motor 118 is housed within the motor housing 114. A propulsion component 120 that generates the propulsion air-flow 110 is coupled to the motor 118. An electronics assembly 122 is disposed on the end face 116 of the motor housing 114. The electronics assembly 122 includes the electronic device casing 102 that houses the one or more electronic devices 104. The plurality of fins 106 extend from the electronic device casing 102. The electronics assembly 122 also includes the one or more fluidic oscillators 108 that receive the propulsion air-flow 110 and provide the oscillatory air-flow 112 over the electronic device casing 102 and the plurality of fins 106.

The motor 118 is housed in the motor housing 114. The motor 118 may be coupled to the motor housing 114 through bolts, screws, adhesive, or any other suitable coupling means. The motor 118 may be a DC motor, an AC motor, or any other suitable electric motor. The motor 118 may be coupled to the electronic devices 104, such as the power module. The power module may be rechargeable, exchangeable, or both. The motor 118 is also coupled to the propulsion component 120 in order to provide power to the propulsion component 120.

The propulsion component 120 may be a propeller, a turbofan, a turbine, or any other device capable of producing an air-flow. The propulsion component 120 utilizes surrounding air to generate the propulsion air-flow 110. The electronic device casing 102 and the plurality of fins 106 are downstream the propulsion air-flow 110. Thus, the propulsion air-flow 110 flows over the electronic device casing 102 and the plurality of fins 106, drawing heat generated by the electronic devices 104 away from the electronic device casing 102 and the plurality of fins 106 and expelling it into the atmosphere. The fluidic oscillators 108 are also downstream the propulsion air-flow 110 so that the fluidic oscillators 108 receive the propulsion air-flow 110 and provide the oscillatory air-flow 112 over the electronic device casing 102 and the plurality of fins 106, further expelling heat generated by the electronic devices 104 and the motor 118 into the atmosphere. The fluidic oscillators 108 may also act as one of the plurality of fins 106 to further dissipate heat from the electronic devices 104.

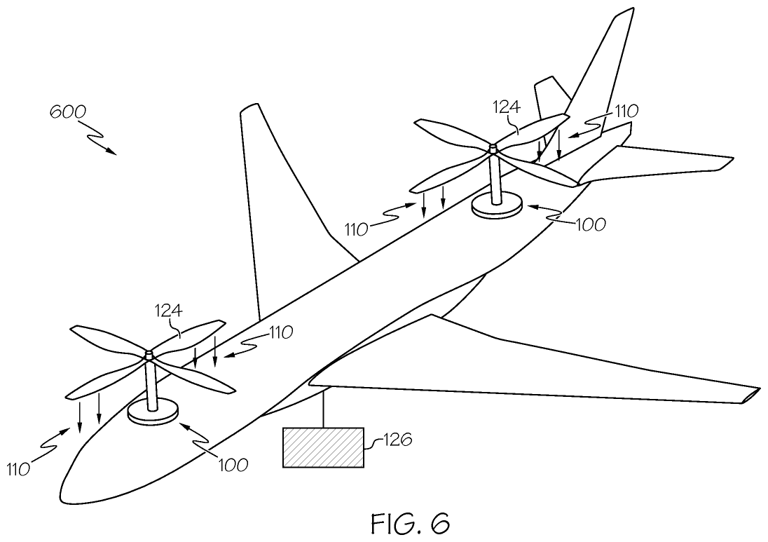

Now referring to FIG. 6, in some embodiments, an eVTOL system 600 includes the motor housing 114 with the end face 116. The motor 118 is housed within the motor housing 114. At least one propeller 124 is mechanically coupled to the motor 118. The at least one propeller 124 generates the propulsion air-flow 110 downstream the at least one propeller 124. The eVTOL system 600 further includes the electronics assembly 122 disposed on the end face 116 of the motor housing 114. The electronics assembly 122 includes the electronic device casing 102 that houses the one or more electronic devices 104. The plurality of fins 106 extend from the electronic device casing 102. The electronics assembly 122 also includes the one or more fluidic oscillators 108 that receive the propulsion air-flow 110 and provide the oscillatory air-flow 112 over the electronic device casing 102 and the plurality of fins 106.

The eVTOL system 600 may be capable of carrying a load 126, passengers, or a combination thereof. The eVTOL system 600 may be controlled in a variety of manners. In some embodiments, the eVTOL system 600 may be controlled through the use of a user controller. The controller may be any device that a user can manipulate to control the eVTOL system 600. The controller may also be integrated into a user device, such as in an application on the user device that the user can interact with to control the eVTOL system 600. The eVTOL system 600 may also be autonomous. The eVTOL system 600 may be controlled in accordance with a predefined set of instructions. The eVTOL system 600 may also integrate machine-learning. The eVTOL system 600 may adjust its predefined set of instructions based on previous trips/iterations.

It should now be understood that embodiments of the present disclosure are directed to assemblies and systems that provide enhanced cooling of electronics of an aircraft. Fluidic oscillators may cool motors and electronic devices within aircrafts, specifically, within eVTOL aircrafts. The fluidic oscillators may be placed on an electronic device casing and provide increased air-flow over the electronic device casing and fins extending from the electronic device casing, dissipating heat produced by the motors and electronic devices. This allows for continuous operation of the aircraft, even when the motor and electronic devices are subject to increased power demands, and increased operational life of aircraft components.

It is noted that recitations herein of a component of the present invention being “configured” in a particular way, “configured” to embody a particular property, or function in a particular manner, are structural recitations as opposed to recitations of intended use. More specifically, the references herein to the manner in which a component is “configured” denotes an existing physical condition of the component and, as such, is to be taken as a definite recitation of the structural characteristics of the component.

It is noted that one or more of the following claims utilize the term “wherein” as a transitional phrase. For the purposes of defining the present invention, it is noted that this term is introduced in the claims as an open-ended transitional phrase that is used to introduce a recitation of a series of characteristics of the structure and should be interpreted in like manner as the more commonly used open-ended preamble term “comprising”.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

1. An impingement cooling system comprising:
an electronic device casing configured to house one or more electronic devices, wherein the electronic device casing is downstream of a propulsion air-flow;
a plurality of fins extending from the electronic device casing; and
one or more fluidic oscillators coupled to the electronic device casing, wherein the one or more fluidic oscillators receive the propulsion air-flow and provide an oscillatory air-flow over the electronic device casing and the plurality of fins.

2. The impingement cooling system of claim 1, wherein the one or more fluidic oscillators is a feedback-free fluidic oscillator.

3. The impingement cooling system of claim 1, wherein the one or more fluidic oscillators is a double-feedback fluidic oscillator.

4. The impingement cooling system of claim 1, wherein the one or more fluidic oscillators comprise a feedback-free fluidic oscillator and a double-feedback fluidic oscillator.

5. The impingement cooling system of claim 1, wherein a plurality of power modules are housed on an inside wall of the electronic device casing.

6. The impingement cooling system of claim 1, wherein the oscillatory air-flow is configured to oscillate laterally with respect to the propulsion air-flow.

7. The impingement cooling system of claim 1, wherein the oscillatory air-flow is configured to oscillate longitudinally with respect to the propulsion air-flow.

8. The impingement cooling system of claim 1, wherein a motor is housed within the electronic device casing.

9. The impingement cooling system of claim 8, wherein the motor is coupled to a propulsion component.

10. The impingement cooling system of claim 1, wherein the one or more fluidic oscillators is 3-D printed.

11. The impingement cooling system of claim 1, wherein the one or more fluidic oscillators is integrally formed onto the electronic device casing.

12. An electric motor assembly comprising:
a motor housing having an end face;
a motor within the motor housing;
a propulsion component coupled to the motor, wherein the propulsion component generates a propulsion air-flow downstream the propulsion component; and
an electronics assembly disposed on the end face of the motor housing, the electronics assembly comprising:
an electronic device casing configured to house one or more electronic devices, wherein the electronic device casing is downstream the propulsion air-flow;
a plurality of fins extending from the electronic device casing; and
one or more fluidic oscillators coupled to the electronic device casing, wherein the one or more fluidic oscillators receive the propulsion air-flow and provide an oscillatory air-flow over the electronic device casing and the plurality of fins.

13. The electric motor assembly of claim 12, wherein the propulsion component is a propeller.

14. The electric motor assembly of claim 12, wherein the one or more electronic devices is a power module.

15. The electric motor assembly of claim 12, wherein the one or more fluidic oscillators act as one of the plurality of fins.

16. An eVTOL system comprising:
a motor housing having an end face;
a motor within the motor housing;
at least one propeller mechanically coupled to the motor, wherein the at least one propeller generates a propulsion air-flow downstream the at least one propeller; and
an electronics assembly disposed on the end face of the motor housing, the electronics assembly comprising:
an electronic device casing configured to house one or more electronic devices, wherein the electronic device casing is downstream the propulsion air-flow;
a plurality of fins extending from the electronic device casing; and
one or more fluidic oscillators coupled to the electronic device casing, wherein the one or more fluidic oscillators are configured to receive the propulsion air-flow and provide an oscillatory air-flow over the electronic device casing and the plurality of fins.

17. The eVTOL system of claim 16, wherein the one or more fluidic oscillators are coupled between each set of the plurality of fins.

18. The eVTOL system of claim 16, wherein the eVTOL system is capable of carrying a load of at least 25 pounds.

19. The eVTOL system of claim 16, wherein the eVTOL system is controlled through a user controller.

20. The eVTOL system of claim 16, wherein the eVTOL system is autonomous.
